(19) United States
(12) Patent Application Publication
(10) Pub. No.: US 2009/0091945 A1
(43) Pub. Date: Apr. 9, 2009

(54) Coloured Polyurethane Light Guides

(75) Inventor: Edmond Kenneth Joseph, Queensland (AU)

Correspondence Address: HARNESS, DICKEY & PIERCE, P.L.C., P.O. BOX 828, BLOOMFIELD HILLS, MI, 48303, US

(73) Assignee: POLY OPTICS AUSTRALIA PTY LTD., Queensland (AU)

(21) Appl. No.: 11/991,822

(22) PCT Filed: Sep. 15, 2006
(86) PCT No.: PCT/AU2006/001360

§ 371 Date: May 22, 2008

(30) Foreign Application Priority Data
Sep. 16, 2005 (AU) 2005905121

(51) Int. Cl. H01L 33/00; G02B 6/00; A44C 5/00

(52) U.S. Cl. 362/555; 362/582; 362/571

(57) ABSTRACT

An optical illumination device (20) comprises a light guide (10) formed from an unclad flexible polyurethane fibre (12), which comprises a transparent polyurethane region (14) and an adjacent coloured polyurethane region (16). The device comprises at least one illumination module (22) coupled to at least one end of the light guide and the illumination module comprises at least one light source (24) for illuminating the light guide.

### FIELD OF THE INVENTION

The present invention relates to flexible optical fibres or light guides. In particular, the present invention relates to light guides formed from polyurethane.

### BACKGROUND TO THE INVENTION

Optical fibres are being used in a wide variety of applications. The majority of these applications employ the optical fibres for their light transmitting properties. For example, it is known that coherent optical radiation from a laser source can be transmitted along a suitable optical fibre for many hundreds of kilometres.

In addition to communications applications, optical fibres have found applications in domestic articles, such as lamps comprising multiple fibres, and novelty items, such as illuminated bracelets, necklaces, shoelaces and the like. One of the Applicant's co-pending patent applications describes a light guide formed from an unclad flexible polyurethane fibre that produces significant side scattering over distances of up to about 1 metre.

Nonetheless, as in other fields, users of such articles are always in search of new and more interesting forms and therefore there is a desire for further applications utilising novel optical fibres.

In this specification, the terms “comprises”, “comprising”, “includes”, “including” or similar terms are intended to mean a non-exclusive inclusion, such that a method, system or apparatus that comprises a list of elements does not include those elements solely, but may well include other elements not listed.

### OBJECT OF THE INVENTION

It is an object of the present invention to provide a flexible light guide that provides an enhanced illumination effect in comparison to conventional urethane light guides when illuminated.

Further objects will be evident from the following description.

### SUMMARY OF THE INVENTION

In one form, although it need not be the only or indeed the broadest form, the invention resides in a light guide formed from an unclad, flexible polyurethane fibre, said fibre comprising a transparent polyurethane region and an adjacent coloured polyurethane region.

Optionally, the transparent polyurethane region and the adjacent coloured polyurethane region are substantially planar, co-extruded strips.

Optionally, a cross-sectional area of the transparent polyurethane region is greater than a cross-sectional area of the coloured polyurethane region.

Optionally, the coloured polyurethane region is a substantially planar strip and the adjacent transparent polyurethane region comprises a shaped cross-section.

In another form, the invention resides in an optical illumination device comprising:

a light guide formed from an unclad, flexible polyurethane fibre, said fibre comprising a transparent polyurethane region and an adjacent coloured polyurethane region; and

at least one illumination module coupled to at least one end of the light guide, said illumination module comprising at least one light source for illuminating the light guide.

Suitably, the coloured polyurethane region forms an inner region the fibre and the transparent polyurethane region forms an outer region of the fibre.

Suitably, the optical illumination device is one of the following: a personal adornment such as, but not limited to, a bracelet, necklace, headband or shoelace, a toy or plaything, such as a skipping rope, hoola-hoop, gymnastic article or the like.

Suitably, the illumination module is coupled to both ends of the light guide.

Preferably, the at least one light source is a light emitting diode (LED).

Suitably, the illumination module emits one or more colours.

Suitably, the illumination module causes the light emitted by the at least one light source to cycle through a range of colours.

Suitably, light emitted from a first light source is synchronized with light emitted from one or more second and further light sources of the illumination module.

Suitably, the coloured region of the fibre is coaxial with the transparent region along at least part of the length of the fibre.

Optionally, the coloured region of the fibre is offset with respect to the transparent region of the fibre along at least part of the length of the fibre. The offset may vary along at least part of the length of the fibre.

Optionally, a cross-sectional shape of the coloured region of the fibre is the same as, or different from, the transparent region of the fibre along at least part of the length of the fibre.

Suitably, the coloured region of the fibre is a single colour or varies in colour along at least part of the length of the fibre.

Suitably, the coloured region of the fibre is patterned along at least part of the length of the fibre.

Further features of the present invention will become apparent from the following detailed description.

### BRIEF DESCRIPTION OF THE DRAWINGS

By way of example only, preferred embodiments of the invention will be described more fully hereinafter with reference to the accompanying drawings, wherein:

FIG. 1 shows a length of a light guide according to an embodiment of the present invention;

FIG. 2 shows a cross-sectional view through section line 2-2 of the light guide of FIG. 1;

FIG. 3 shows an optical illumination device according to a first embodiment of the present invention;

FIG. 4 shows an optical illumination device according to a second embodiment of the present invention;

FIG. 5 shows an example of a circuit suitable for an embodiment of the illumination module of the optical illumination device shown in FIG. 2; and

FIGS. 6A-6C show alternative embodiments of the light guide according to other embodiments of the present invention.

### DETAILED DESCRIPTION OF THE INVENTION

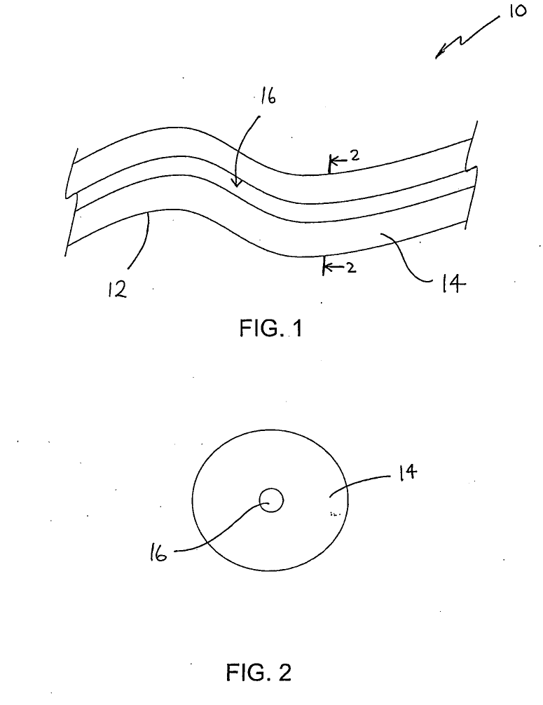

Referring to FIG. 1, there is provided in accordance with an embodiment of the present invention a side-scattering light guide 10 formed from an unclad, flexible polyurethane fibre 12. The fibre 12 comprises a transparent polyurethane region 14 and an adjacent coloured polyurethane region 16. In the embodiment shown in FIG. 1, the coloured polyurethane region 16 forms an inner region of the fibre and the transparent polyurethane region 14 forms an outer region of the fibre.

The light guide 10 side scatters light over the entire length of the fibre 12. The inventors have found that there is less attenuation along the length of the fibre 12 in the coloured polyurethane region 16 than in the transparent polyurethane region 14 and the coloured polyurethane region 16 produces enhanced light leakage properties of flexible polyurethane light guides that make it useful for many novelty applications.

The light guide 10 is typically extruded using known extrusion techniques, although it can also be cast in a rod or sheet form. In one embodiment, the transparent polyurethane region 14 and the coloured polyurethane region 16 are co-extruded. For most applications an elongate fibre is preferred. According to one embodiment, the extrusion conditions are set to be too quick or too slow according to conventional extruding parameters. This causes some yellowing of the extruded guide, but also leads to scattering due to imperfections in the guide. In addition, the guide is used unclad so that light leaks from the guide over its length. In an alternative embodiment, extrusion conditions are set to avoid or at least minimise the impurities. In this embodiment, side scattering in the light guide can be achieved by the introduction of light diffusing particles or “diffuser” particles into the transparent polyurethane region 14 and/or the coloured polyurethane region 16 as disclosed in the Applicant's earlier international patent application no. WO 02/095289.

A typical length of the light guide 10 is about several metres or less and a typical diameter is up to about 10 millimetres and can be as small as about one hundred microns. FIG. 2 shows a cross sectional view of the light guide shown in FIG. 1 showing the relative dimensions of the transparent polyurethane outer region 14 and the coloured polyurethane inner region 16 of the fibre. In this embodiment of the light guide 10, the diameter of the transparent polyurethane outer region 14 is about 7 millimetres and the diameter of the coloured polyurethane inner region 16 is about 1 millimetre. However, it should be appreciated that the diameters of the inner and outer regions can vary in alternative embodiments and the diameter of the inner region 16 can form any percentage less than 100% of the diameter of the outer region 14.

In one embodiment, the coloured inner region 16 of the fibre is the same shape as, and coaxial with, the transparent outer region 14 along at least part of the length of the fibre 10. As shown in FIG. 2, in one embodiment, both the inner and outer regions 16, 14 are circular in cross-section. Alternatively, the inner and/or outer regions 16, 14 can be extruded in different shapes. For example, the outer region may remain circular in cross section and the inner region 16 can be extruded in, for example, a star shape to produce an interesting lighting effect and enhance the aesthetic appeal of the light guide 10. In another embodiment, the inner region 16 can be offset with respect to the outer region 14 such that they are not coaxial. In some embodiments, the offset can vary along the length of the fibre such that the coloured inner region 16 produces, for example, a spiral effect.

With reference to FIG. 6A, in a further embodiment, the side-scattering light guide 10 comprises transparent region 14 in the form of a thin, rectangular, substantially planar strip of transparent polyurethane and coloured region 16 in the form of an adjacent, co-extruded, thin, rectangular, substantially planar strip of coloured polyurethane. Alternatively, a cross-sectional area of the transparent polyurethane region 14 is greater than a cross-sectional area of the coloured polyurethane region 16. For example, transparent region 14 has a square cross-section as shown in FIG. 6B or a hemispherical cross-section as shown in FIG. 6C or some other shape and the coloured polyurethane region 16 co-extruded, thin, rectangular, substantially planar strip.

The coloured region 16 of the fibre can be any colour or combination of colours including any fluorescent or luminous colour or combination thereof. The colour can be achieved using any suitable dyes or colouring agent. For example, dyes derived from or based on perylene tetracarbonic acid, such as Lumogen® dyes from the BASF Group or other dyes, such as EP7701 colouring agents from Eager Plastics, Inc. USA are suitable because of the vivid colours achievable, their ease of use, their lack of odour and toxicity and their high lightfast nature. According to one embodiment, the coloured region 16 is a single, constant colour along the length of the fibre. Alternatively, the colour varies along at least part of the length of the fibre. The colour variation can be abrupt or gradual. Alternatively, the coloured region 16 of the fibre is patterned along at least part of the length of the fibre.

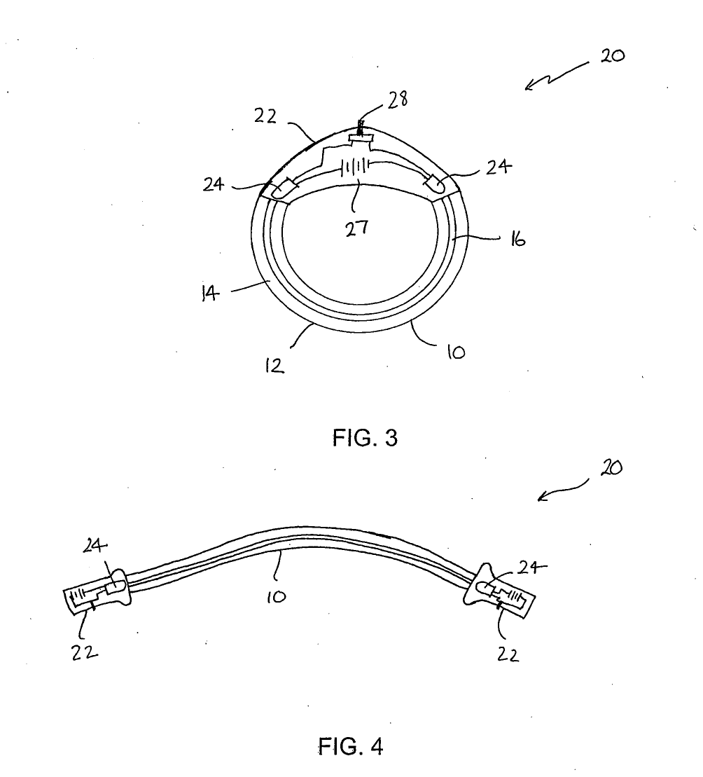

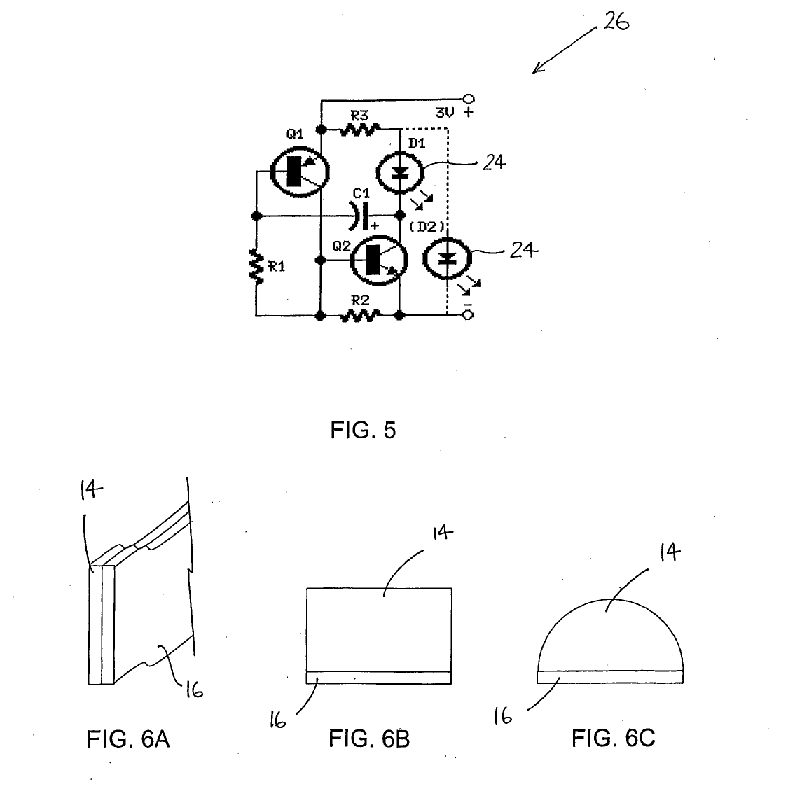

With reference to FIG. 3, one particular application of the light guide 10 is in an optical illumination device 20 comprising the light guide 10 coupled to at least one illumination module 22. The illumination module 22 comprises at least one light source 24 for illuminating the light guide 10, a power supply 27 and a switch 28. FIG. 3 shows a simplified circuit and an example of a full circuit 26 is shown in FIG. 5. In most applications the light source 24 is a light emitting diode (LED), as is known in the art. As will be appreciated by persons skilled in the art other light sources will be possible, but may not be suitable in the majority of applications, for example, due to their size and/or power consumption.

In this embodiment, where the optical illumination device 20 is a novelty item, such as a necklace or bracelet or the like, as shown in FIG. 3, both ends of the light guide 10 are coupled to the illumination module 22 and the illumination module 22 comprises two or more light sources 24 with at least one light source aligned with each end of the light guide 10.

With reference to FIG. 4, in an alternative embodiment, the optical illumination device 20 is a toy or plaything such as a skipping rope. In this embodiment, the optical illumination device 20 comprises a pair of illumination modules 22, which form the handles of the skipping rope and the light guide 10 forms the rope of the skipping rope. One end of the light guide 10 is coupled to one of the illumination modules 22 and the other end of the light guide 10 is coupled to a second illumination module 22. In this embodiment, each illumination module 22 comprises a single light source 24 aligned with a respective end of the light guide 10, a power supply 27 and a switch 28. It will be appreciated that multiple light sources 24 can be provided in each illumination module 22.

In one embodiment, the illumination module 22 comprises a known circuit 26 as shown in FIG. 5, which comprises two light sources 24 in the form of LEDs D1 and D2 and a 4.5V power supply provided by three 1.5 v LR44 button batteries or similar. In circuit 26, R1 is a 33K ¼ W resistor and R2 and R3 are 47R ¼ W resistors. C1 is a 10 μF 25V electrolytic capacitor, Q1 is a BC560 45V 100 mA PNP transistor, Q2 is a BC337 45V 800 mA NPN transistor and circuit 26 causes the LEDs D1 and D2 to flash alternately. Persons skilled in the art will appreciate that the power supply can vary from about 2-4.5V and the components in the circuit 26 can be varied to vary the flashing frequencies, relative on/off times of the LEDs and the colours emitted by the LEDs or synchronize the light emitted from the light sources 24 in any desired fashion. For example, the circuit 26 can be modified such that the LEDs emit a range of colours and the colours are cycled through in a predetermined sequence or at random. Circuit 26 may also comprise the switch 28 to allow the circuit to, be activated and deactivated.

In the skipping rope example, according to one embodiment, light emitted from a first illumination module 22 is synchronised with light emitted from a second illumination module 22 to produce an appealing effect.

In various embodiments of the present invention, the illumination module 22 is a sealed unit to prevent small parts, such as the batteries or LEDs, from being removed by children and presenting a choking risk or other hazard. The sealed unit also protects the components therein.

The light guide 10 can also be produced as a cast sheet or extruded into different continuous shapes, such as an oval, a star, or a complex shape that would slide easily into a track.

The invention finds numerous uses in novelty applications where a flexible light guide is required which gives off a distinctive glow or side illumination. Such applications include, but are not limited to: adornments such as necklaces, bracelets and hand bags; toys, games and playthings, such as skipping ropes, hoola-hoop-type items and gymnastic articles; footwear including laces; weaved into textiles for clothing; safety apparel such as bike helmets and hard hats.

Hence, the present invention provides an enhanced side scattering illumination effect in comparison to conventional urethane light guides when illuminated by virtue of the transparent polyurethane region 14 having an adjacent coloured polyurethane region 16. The urethane light guides 10 and the illumination module 22 of the present invention are robust and durable which are desirable characteristics for many applications, in particular children's toys, clothing and safety apparel. The light guides 10 of the present invention can be bent into small radii without cracking or breaking or losing their light transmission and light scattering characteristics.

Throughout the specification the aim has been to describe the invention without limiting the invention to any one embodiment or specific collection of features. Persons skilled in the relevant art may realize variations from the specific embodiments that will nonetheless fall within the scope of the invention.

1. An optical illumination device comprising:
a light guide formed from an unclad, flexible polyurethane fibre, said fibre comprising a transparent polyurethane region and an adjacent coloured polyurethane region; and
at least one illumination module coupled to at least one end of the light guide, said illumination module comprising at least one light source for illuminating the light guide.

2. The optical illumination device as claimed in claim 1, wherein the coloured polyurethane region forms an inner region of the fibre and the transparent polyurethane region forms an outer region of the fibre.

3. The optical illumination device as claimed in claim 1, wherein the illumination module is coupled to both ends of the light guide.

4. The optical illumination device as claimed in claim 1, wherein the at least one light source is a light emitting diode (LED).

5. The optical illumination device as claimed in claim 1, wherein the at least one light source of the illumination module emits one or more colours.

6. The optical illumination device as claimed in claim 1, wherein the illumination module causes the light emitted by the at least one light source to cycle through a range of colours.

7. The optical illumination device as claimed in claim 1, wherein light emitted from a first light source is synchronized with light emitted from one or more second and further light sources of the illumination module.

8. The optical illumination device as claimed in claim 1, wherein the coloured region of the fibre is coaxial with the transparent region of the fibre along at least part of the length of the fibre.

9. The optical illumination device as claimed in claim 1, wherein the coloured region of the fibre is offset with respect to the transparent region of the fibre along at least part of the length of the fibre.

10. The optical illumination device as claimed in claim 9, wherein the offset of the coloured region of the fibre varies along at least part of the length of the fibre.

11. The optical illumination device as claimed in claim 1, wherein a cross-sectional shape of the coloured region of the fibre is the same as the transparent region of the fibre along at least part of the length of the fibre.

12. The optical illumination device as claimed in claim 1, wherein a cross-sectional shape of the coloured region of the fibre is different from the transparent region of the fibre along at least part of the length of the fibre.

13. The optical illumination device as claimed in claim 1, wherein the coloured region of the fibre and/or the transparent region of the fibre comprise light diffusing particles.

14. The optical illumination device as claimed in claim 1, wherein the coloured region of the fibre is a single colour.

15. The optical illumination device as claimed in claim 1, wherein the coloured region of the fibre varies in colour along at least part of the length of the fibre.

16. The optical illumination device as claimed in claim 1, wherein the coloured region of the fibre is patterned along at least part of the length of the fibre.

17. The optical illumination device as claimed in claim 1, wherein the coloured polyurethane region of the fibre comprises one or more colours achieved using one or more fluorescent dyes.

18. The optical illumination device as claimed in claim 17, wherein the one or more fluorescent dyes are based on perylene tetracarbonic acid.

19. The optical illumination device as claimed in claim 1, wherein the optical illumination device is one of the following: a personal adornment, a bracelet, a necklace, a headband, a shoelace, a toy, a plaything, a skipping rope, a hoola-hoop, a gymnastic article.

20. A light guide formed from an unclad, flexible polyurethane fibre, said fibre comprising a transparent polyurethane region and an adjacent coloured polyurethane region.

21. The light guide as claimed in claim 18, wherein the transparent polyurethane region and the adjacent coloured polyurethane region are substantially planar, co-extruded strips.

22. The light guide as claimed in claim 18, wherein a cross-sectional area of the transparent polyurethane region is greater than a cross-sectional area of the coloured polyurethane region.

23. The light guide as claimed in claim 20, wherein the coloured polyurethane region is a substantially planar strip and the adjacent transparent polyurethane region comprises a shaped cross-section.
